(19) United States
(12) Patent Application Publication
(10) Pub. No.: US 2023/0231490 A1
(43) Pub. Date: Jul. 20, 2023

(54) POWER CONVERTER AND AIR CONDITIONER

(71) Applicant: Mitsubishi Electric Corporation, Tokyo (JP)

(72) Inventors: Keisuke UEMURA, Tokyo (JP); Shotaro KARASUYAMA, Tokyo (JP); Koichi ARISAWA, Tokyo (JP); Takaaki TAKAHARA, Tokyo (JP)

(21) Appl. No.: 18/007,106

(22) PCT Filed: Sep. 4, 2020
(86) PCT No.: PCT/JP2020/033558

§ 371 Date: Jan. 27, 2023

(51) Int. Cl. H02M 7/219; H02M 1/00; H03K 17/042; H02P 27/06

(52) U.S. Cl. CPC H02M 7/219; H02M 1/0009; H02P 27/06; H03K 17/04206; H02M 1/126

(57) ABSTRACT

A power converter includes: a converter including four switching elements in full bridge configuration, the converter converting alternating-current power supplied from an alternating-current power supply into direct-current power; a reactor provided between the alternating-current power supply and the converter; a smoothing capacitor connected between direct-current terminals of the converter; an alternating-current voltage detector detecting an alternating-current voltage output from the alternating-current power supply; an alternating current detector detecting a current flowing through the reactor; and a control circuitry controlling a switching operation of the switching elements. The control circuitry controls the switching elements such that a potential fluctuation due to the switching operation is reduced between a P terminal of the converter and an L terminal of the alternating-current power supply, or between a G terminal of the converter and an N terminal of the alternating-current power supply.

### CROSS-REFERENCE TO RELATED APPLICATION

[0001A] This application is a U.S. National Stage Application of International Application No. PCT/JP2020/033558 filed on Sep. 4, 2020, the contents of which are incorporated herein by reference.

### TECHNICAL FIELD

[0001B] The present disclosure relates to a power converter that converts alternating-current power into direct-current power and an air conditioner.

### BACKGROUND

Power converters that convert alternating-current power into direct-current power are mounted on trains, automobiles, and devices such as air conditioners. Inverters each convert direct-current power output from such a power converter into alternating-current power of a specified frequency and supply the alternating-current power to a load such as a motor. The power converters are required to achieve energy saving and noise reduction. In order to achieve energy saving and noise reduction, Patent Literature 1 discloses a technique of stopping switching of a converter during a period in which a power supply current is zero.

### PATENT LITERATURE

Patent Literature 1: Japanese Patent Application Laid-open No. 2017-55489

In general, a power factor improvement converter is provided with control to bring a duty ratio close to 1 when a power supply current is near zero-crossing, and Patent Literature 1 is no exception. However, in the technique described in Patent Literature 1, the switching by the power factor improvement converter is stopped when the power supply current is near zero-crossing for the purpose of suppression of noise. Therefore, in a method of Patent Literature 1, two inconsistent types of control including control to bring an original duty ratio close to 1 and control to stop switching for suppression of noise are incorporated, and thus it is difficult to achieve both suppression of noise and stability of control, which is a problem.

### SUMMARY

The present disclosure has been made in view of the above, and an object thereof is to obtain a power converter capable of achieving both suppression of noise and stability of control.

To solve the above problems and achieve the object, a power converter according to the present disclosure includes: a converter including four switching elements in a full bridge configuration, the converter is adapted to convert alternating-current power supplied from an alternating-current power supply into direct-current power; a reactor provided between the alternating-current power supply and the converter; a smoothing capacitor connected between direct-current terminals of the converter; an alternating-current voltage detector adapted to detect an alternating-current voltage output from the alternating-current power supply; an alternating current detector adapted to detect a current flowing through the reactor; and a control circuitry adapted to control a switching operation of the switching elements. The control circuitry is adapted to control the switching elements such that a potential fluctuation due to the switching operation is suppressed: between a P terminal and an L terminal; or between a G terminal and an N terminal. The P terminal is a positive direct-current terminal of the converter, the L terminal is one terminal of the alternating-current power supply, the G terminal is a negative direct-current terminal of the converter, and the N terminal is another terminal of the alternating-current power supply.

The power converting apparatus according to the present disclosure achieves an effect that it is possible to achieve both suppression of noise and stability of control.

### BRIEF DESCRIPTION OF DRAWINGS

FIG. 1 is a diagram illustrating an example configuration of a power converter according to a first embodiment.

FIG. 2 is a diagram illustrating an example configuration in a state where a common mode choke coil and a Y capacitor which are noise filters are connected to the power converter according to the first embodiment.

FIG. 3 is a diagram illustrating an example of a switching method of switching elements of a converter included in the power converter according to the first embodiment.

FIG. 4 is a diagram illustrating examples of a current path when the switching elements of the converter included in the power converter according to the first embodiment are switched by gate signals illustrated in FIG. 3.

FIG. 5 is a diagram illustrating an example configuration of a control circuitry included in the power converter according to the first embodiment.

FIG. 6 is a diagram illustrating an example operation of a power supply voltage phase calculator included in the control circuitry of the power converter according to the first embodiment.

FIG. 7 is a diagram illustrating an example configuration of a pulse generator included in the control circuitry of the power converter according to the first embodiment.

FIG. 8 is a diagram for explaining a method for generating a high-speed switching signal and an inverted synchronous rectification signal generated by the pulse generator included in the control circuitry of the power converter according to the first embodiment.

FIG. 9 is a first flowchart illustrating an operation of a pulse selector included in the control circuitry of the power converter of the first embodiment.

FIG. 10 is a second flowchart illustrating the operation of the pulse selector included in the control circuitry of the power converter of the first embodiment.

FIG. 11 is a diagram illustrating examples of signal waveforms in consideration of a dead time in the switching elements included in the converter of the power converter according to the first embodiment.

FIG. 12 is a diagram illustrating examples of gate signals in a case of pattern 2 output to the converter by the control circuitry of the power converter according to the first embodiment.

FIG. 13 is a diagram illustrating examples of the gate signals in a case of pattern 3 output to the converter by the control circuitry of the power converter according to the first embodiment.

FIG. 14 is a diagram illustrating examples of the gate signals in a case of pattern 4 output to the converter by the control circuitry of the power converter according to the first embodiment.

FIG. 15 is a diagram illustrating an example of a method for measuring a leakage current flowing through the power converter according to the first embodiment.

FIG. 16 is a diagram illustrating, as comparative examples, examples of the gate signals for the switching elements when the switching elements included in the converter of the power converter are switched in synchronization with an alternating current.

FIG. 17 is a diagram illustrating, as comparative examples, respective signal waveforms and a waveform obtained by measuring a leakage current in a case where the switching elements included in the converter of the power converter operate with the gate signals illustrated in FIG. 16.

FIG. 18 is a diagram illustrating waveforms obtained by measuring respective signals and a leakage current in a case where the switching elements included in the converter of the power converter according to the first embodiment operate with the gate signals illustrated in FIG. 3.

FIG. 19 is a diagram illustrating an example of a hardware configuration that realizes the control circuitry included in the power converter according to the first embodiment.

FIG. 20 is a diagram illustrating an example configuration of the power converter according to a second embodiment.

FIG. 21 is a diagram illustrating examples of a current path when the control circuitry of the power converter according to the second embodiment causes a current to circulate through the switching elements on a low side in a power supply short-circuit mode.

FIG. 22 is a diagram illustrating, as comparative examples, examples of a current path when the control circuitry of the power converter causes a current to circulate through the switching elements on a high side in the power supply short-circuit mode.

FIG. 23 is a diagram illustrating a waveform obtained by measuring a leakage current when a current is caused to circulate through the switching elements on the low side in the power supply short-circuit mode in the power converter according to the second embodiment to which a first diode and a second diode illustrated in FIG. 20 are connected.

FIG. 24 is a diagram illustrating an example configuration of a motor driver according to a third embodiment including the power converter of the first and second embodiments.

FIG. 25 is a diagram illustrating an example configuration of an air conditioner according to the third embodiment including the motor driver illustrated in FIG. 24.

FIG. 26 is a diagram illustrating a part of a propagation path of a leakage current mainly in an outdoor unit in the air conditioner according to the third embodiment.

FIG. 27 is a diagram illustrating a measurement result of a leakage current depending on a compressor rotation speed of a compressor mounted on the air conditioner according to the third embodiment or the like.

### DETAILED DESCRIPTION OF EMBODIMENTS

Hereinafter, a power converter and an air conditioner according to each embodiment of the present disclosure will be described in detail with reference to the drawings.

### First Embodiment

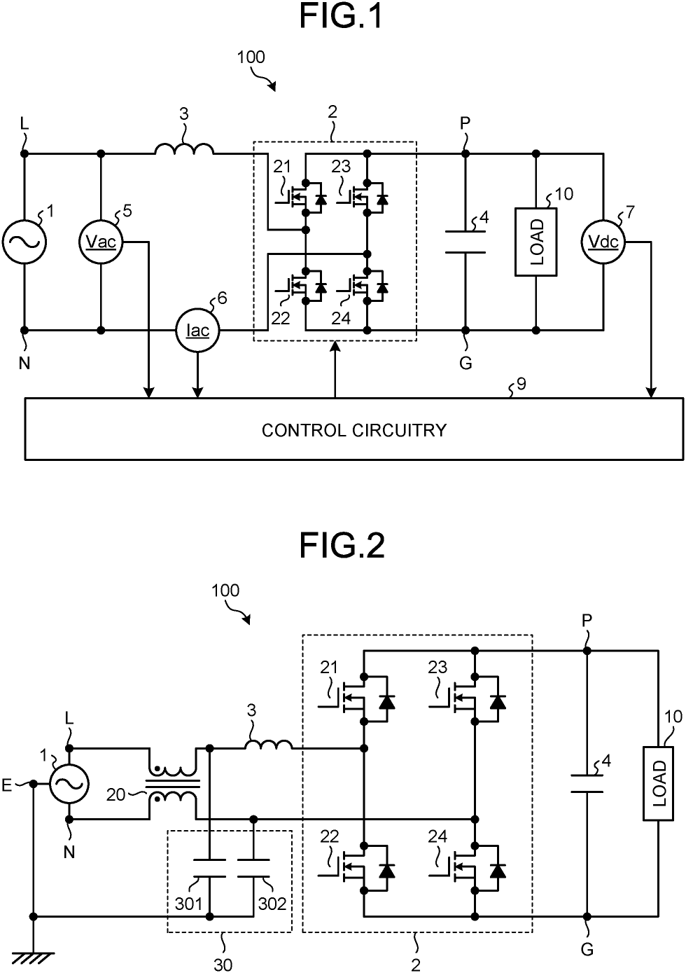

FIG. 1 is a diagram illustrating an example configuration of a power converter 100 according to a first embodiment. The power converter 100 illustrated in FIG. 1 includes: a converter 2; a reactor 3; a smoothing capacitor 4; an alternating-current voltage detector 5; an alternating current detector 6; a direct-current voltage detector 7; and a control circuitry 9. FIG. 1 illustrates a state where an alternating-current power supply 1 and a load 10 are connected to the power converter 100. The converter 2 includes two alternating-current terminals as input terminals and two direct-current terminals as output terminals. Of the direct-current terminals included in the converter 2, a positive terminal is a P terminal, and a negative terminal is a G terminal.

In the power converter 100, an L terminal which is one terminal of the alternating-current power supply 1 is connected to one terminal of the reactor 3; another terminal of the reactor 3 is connected to one alternating-current terminal of the converter 2 including semiconductor elements; and an N terminal which is another terminal of the alternating-current power supply 1 is connected to another alternating-current terminal of the converter 2. The reactor 3 is provided between the alternating-current power supply 1 and the converter 2. The alternating-current voltage detector 5 that detects a power supply voltage output from the alternating-current power supply 1 and input to the converter 2, that is, an alternating-current voltage Vac, is connected in parallel to both ends of the alternating-current power supply 1. The alternating current detector 6, which detects a power supply current output from the alternating-current power supply 1 and input to the converter 2 as an alternating current Iac, is connected in series between the alternating-current power supply 1 and the converter 2. The alternating current detector 6 can detect a current flowing through the reactor 3 by detecting the alternating current Iac. The reactor 3 may be provided between the N terminal which is the another terminal of the alternating-current power supply 1 and the another alternating-current terminal of the converter 2.

The converter 2 converts alternating-current power supplied from the alternating-current power supply 1 into direct-current power. The smoothing capacitor 4, the load 10, and the direct-current voltage detector 7 are each connected in parallel between the direct-current terminals in the converter 2, that is, between the P terminal and the G terminal. The direct-current voltage detector 7 detects a bus voltage Vdc which is a direct-current voltage output from the converter 2. The control circuitry 9 acquires values detected by the alternating-current voltage detector 5, the alternating current detector 6, and the direct-current voltage detector 7, that is, detection results. The control circuitry 9 generates and outputs a control signal for controlling the semiconductor elements of the converter 2 on the basis of the detection results of the alternating-current voltage detector 5, the alternating current detector 6, and the direct-current voltage detector 7. Regarding the alternating-current power input to the converter 2, the power converter 100 performs power factor improvement, bus voltage control, and the like, by controlling the semiconductor elements of the converter 2 on the basis of the detection results of the alternating-current voltage detector 5, the alternating current detector 6, and the direct-current voltage detector 7.

The converter 2 includes, as the semiconductor elements described above, four metal oxide semiconductor field effect transistors (MOSFETs), specifically, switching elements 21 to 24. The converter 2 includes: a first arm in which a source of the switching element 21 and a drain of the switching element 22 are connected in series; and a second arm in which a source of the switching element 23 and a drain of the switching element 24 are connected in series. In the converter 2, the first arm and the second arm are connected in parallel as drains of the switching elements 21 and 23 are connected and sources of the switching elements 22 and 24 are connected. The one alternating-current terminal is connected to a contact point between the switching element 21 and the switching element 22; and the another alternating-current terminal is connected to a contact point between the switching element 23 and the switching element 24. As described above, the converter 2 includes the four switching elements 21 to 24 in a full bridge configuration. Specifically, the control circuitry 9 controls a switching operation of the switching elements 21 to 24 as control of the semiconductor elements of the converter 2.

The semiconductor element used in the converter 2 is not limited to the MOSFET, and may be an insulated gate bipolar transistor (IGBT), a diode, or the like. The semiconductor element used in the converter 2 may be a wide bandgap semiconductor such as GaN or SiC.

FIG. 2 is a diagram illustrating an example configuration in a state where a common mode choke coil 20 and a Y capacitor 30 which are noise filters are connected to the power converter 100 according to the first embodiment. For simplicity of description, the alternating-current voltage detector 5, the alternating current detector 6, the direct-current voltage detector 7, and the control circuitry 9 are not illustrated in FIG. 2, but are actually connected.

In the power converter 100, the common mode choke coil 20 is connected between the alternating-current power supply 1 and the reactor 3. The common mode choke coil 20 has a polarity, and is connected so as to have the same polarity on both an alternating-current power supply 1 side and a load 10 side. The common mode choke coil 20 has an effect of suppressing potential imbalance between two phases of the alternating-current terminals of the converter 2. Therefore, in the power converter 100, connection of the common mode choke coil 20 makes it possible to obtain an effect of suppressing potential indefiniteness caused by potential imbalance of the converter 2 and reducing noise.

The Y capacitor 30 includes a first capacitor 301 and a second capacitor 302. The first capacitor 301 is connected to the L terminal which is one terminal of the alternating-current power supply 1 and an E terminal which is a ground terminal of the alternating-current power supply 1, and is connected in parallel to the alternating-current power supply 1. The second capacitor 302 is connected to the N terminal which is the another terminal of the alternating-current power supply 1 and the E terminal which is the ground terminal of the alternating-current power supply 1, and is connected in parallel to the alternating-current power supply 1. The Y capacitor 30 has an effect of suppressing potential indefiniteness of the converter 2. Therefore, in the power converter 100, connection of the Y capacitor 30 makes it possible to obtain an effect of suppressing potential indefiniteness of the converter 2 and reducing noise.

By the two of the common mode choke coil 20 and the Y capacitor 30 being connected, the power converter 100 can obtain an effect of further suppressing potential indefiniteness of the converter 2. In the power converter 100, the connection order and the number of connections of the common mode choke coil 20 and the Y capacitor 30 illustrated in FIG. 2 are merely examples, and there is no limitation thereto. Regarding the connection order and the number of connections of the common mode choke coil 20 and the Y capacitor 30, the power converter 100 can accommodate various configurations. Although not illustrated, the power converter 100 may be configured to include only the common mode choke coil 20 or only the Y capacitor 30 out of the common mode choke coil 20 and the Y capacitor 30 illustrated in FIG. 2.

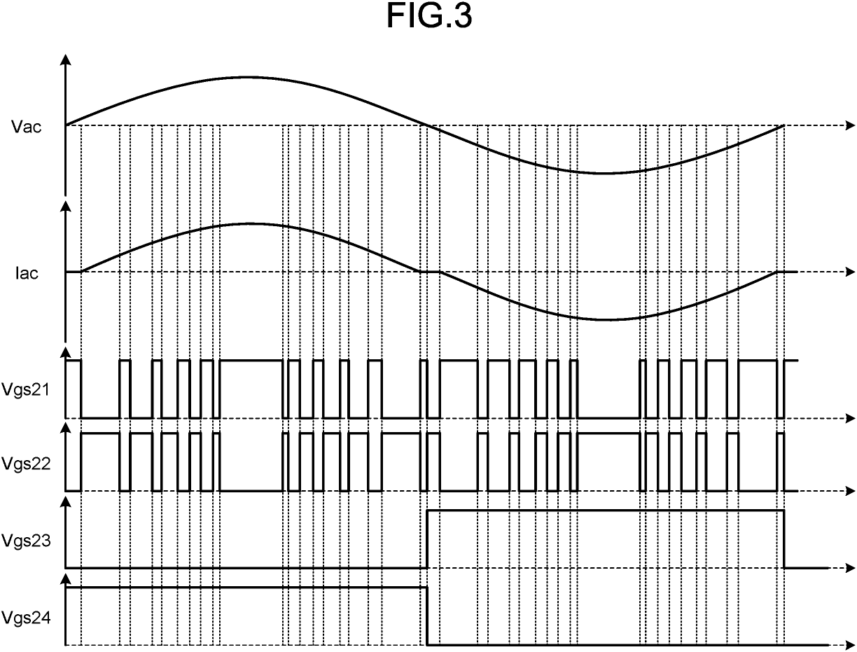

A method for switching the semiconductor elements of the converter 2 included in the power converter 100 will be described. FIG. 3 is a diagram illustrating an example of the method for switching the switching elements 21 to 24 of the converter 2 included in the power converter 100 according to the first embodiment. FIG. 3 illustrates, from the top to the bottom, respective waveforms of the alternating-current voltage Vac, the alternating current Iac, and the gate signals Vgs 21 to Vgs 24 for the switching elements 21 to 24. As illustrated in FIG. 3, the switching elements 21 and 22 perform high-speed switching at a predefined switching frequency during one period of the alternating-current power supply 1 under the control of the control circuitry 9. The switching elements 23 and 24 perform low-speed switching based on the frequency of the alternating-current power output from the alternating-current power supply 1 under the control of the control circuitry 9. As compared with the switching elements 23 and 24 that perform the low-speed switching, the switching elements 21 and 22 that perform the high-speed switching have a high switching speed, that is, have a short ON/OFF interval.

By causing the switching elements 21 and 22 to perform the high-speed switching, the power converter 100 operates in a power supply short-circuit mode and a load power supplying mode, and can improve power factor of the alternating current Iac. In the example of FIG. 3, a gate signal Vgs for one switching element of the switching elements 21 and 22 that perform the high-speed switching is a main signal, and a gate signal Vgs for another switching element thereof is a signal obtained by inversely synchronizing the gate signal Vgs as the main signal. In the switching method illustrated in FIG. 3, the one switching element performing the high-speed switching is inversely synchronized to operate the another switching element, but the another switching element may not be inversely synchronized.

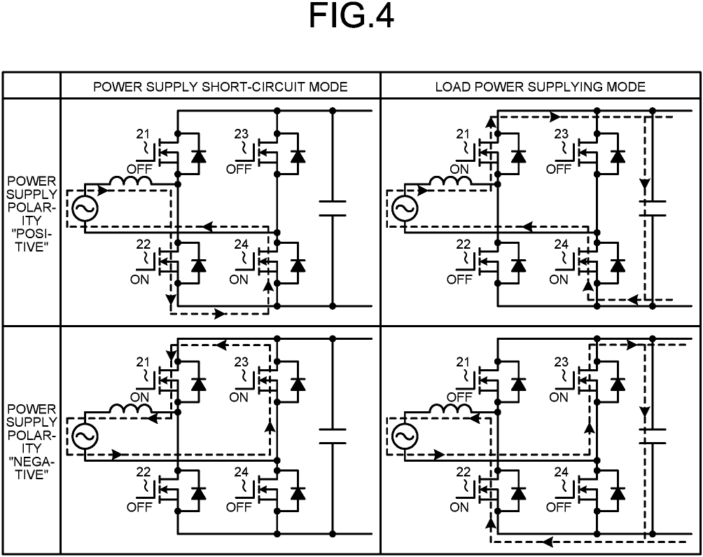

FIG. 4 is a diagram illustrating examples of a current path when the switching elements 21 to 24 of the converter 2 included in the power converter 100 according to the first embodiment are switched by the gate signals Vgs illustrated in FIG. 3. As illustrated in FIG. 4, the power converter 100 inversely synchronizes the another switching element of the switching elements that perform the high-speed switching. Therefore, regarding the switching element 21 in the load power supplying mode when a power supply polarity is positive and the switching element 22 in the load power supplying mode when the power supply polarity is negative, a current passes through between the source and the drain of each of the MOSFETs.

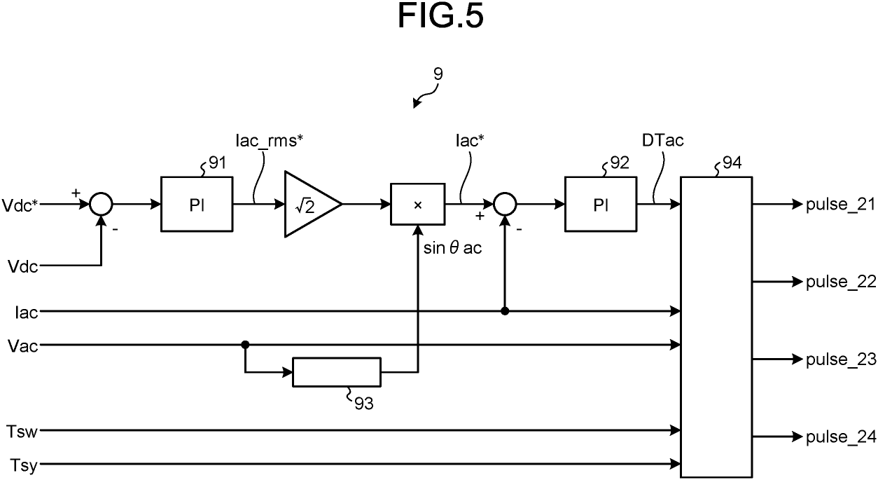

FIG. 5 is a diagram illustrating an example configuration of the control circuitry 9 included in the power converter 100 according to the first embodiment. As illustrated in FIG. 5, the control circuitry 9 includes: a power supply current command value controller 91; an ON-duty controller 92; a power supply voltage phase calculator 93; and a pulse generator 94.

The power supply current command value controller 91 calculates a power supply current RMS command value Iac_rms* using the bus voltage Vdc detected by the direct-current voltage detector 7 and a preset bus voltage command value Vdc*. The calculation of the power supply current RMS command value Iac_rms* is realized by proportional integral (PI) control of a difference between the bus voltage Vdc and the bus voltage command value Vdc*. The proportional integral control is an example, and the power supply current command value controller 91 may adopt proportional (P) control or proportional integral differential (PID) control instead of the proportional integral control.

A switching pattern select signal Tsw and an inverted synchronous rectification select signal Tsy are signals selected by a user of the power converter 100.

The power supply voltage phase calculator 93 generates a power supply voltage phase estimated value θac using the alternating-current voltage Vac detected by the alternating-current voltage detector 5, and outputs a sine value sinθac of the power supply voltage phase estimated value θac.

The ON-duty controller 92 calculates reference ON-duty DTac by using: a power supply current instantaneous command value Iac* calculated from the power supply current RMS command value Iac_rms* output from the power supply current command value controller 91 and the sine value sinθac of the power supply voltage phase estimated value θac output from the power supply voltage phase calculator 93; and the alternating current Iac detected by the alternating current detector 6. The reference ON-duty DTac is calculated by performing proportional integral control on a difference between the power supply current RMS command value Iac_rms* and the alternating current Iac. The proportional integral control is an example, and the ON-duty controller 92 may adopt proportional control or proportional integral differential control instead of the proportional integral control, similarly to the power supply current command value controller 91.

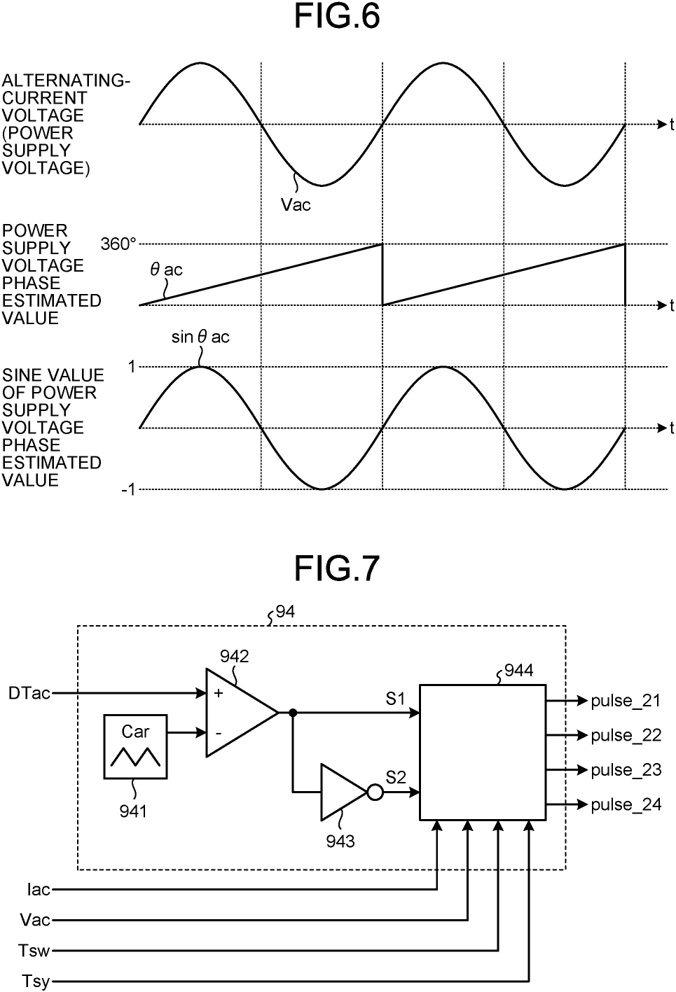

FIG. 6 is a diagram illustrating an example operation of the power supply voltage phase calculator 93 included in the control circuitry 9 of the power converter 100 according to the first embodiment. FIG. 6 illustrates waveforms under an ideal condition in which a delay due to control or a delay due to a detection process is not considered. As illustrated in FIG. 6, the power supply voltage phase estimated value θac is 360° at a point where the alternating-current voltage Vac which is a power supply voltage switches from a negative polarity to a positive polarity. The power supply voltage phase calculator 93 detects the point where the alternating-current voltage Vac switches from the negative polarity to the positive polarity, and resets the power supply voltage phase estimated value θac, that is, returns the value to zero, at the point of switching. In a case where an interruption function of a microcomputer is used in the power supply voltage phase calculator 93, a circuit for detecting the zero-crossing of the alternating-current voltage Vac may be added to FIG. 5. In any case, any method may be used as long as the phase of the alternating-current voltage Vac can be detected.

FIG. 7 is a diagram illustrating an example configuration of the pulse generator 94 included in the control circuitry 9 of the power converter 100 according to the first embodiment. The pulse generator 94 includes an internal carrier generator 941, a comparator 942, a NOT circuit 943, and a pulse selector 944. The internal carrier generator 941 generates an internal carrier Car. The pulse generator 94 includes the internal carrier generator 941 in the example of FIG. 7, but may not include the internal carrier generator 941 in a case where a carrier from the outside is used. The comparator 942 acquires the reference ON-duty DTac calculated by the ON-duty controller 92 and the internal carrier Car generated by the internal carrier generator 941. The comparator 942 generates a high-speed switching signal S1 by comparing a magnitude relationship between the reference ON-duty DTac and the internal carrier Car.

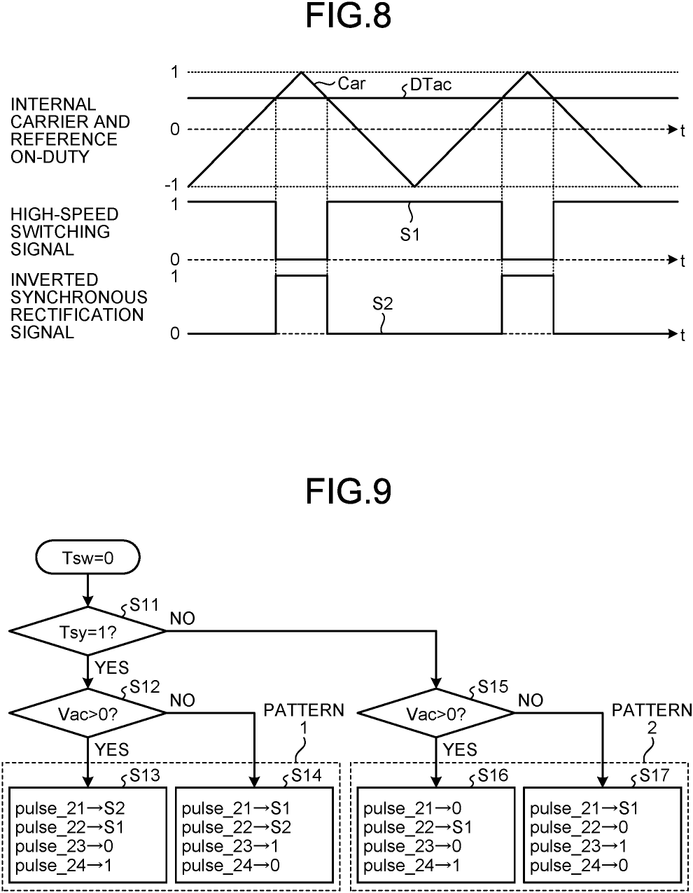

FIG. 8 is a diagram for explaining a method for generating the high-speed switching signal S1 and an inverted synchronous rectification signal S2 generated by the pulse generator 94 included in the control circuitry 9 of the power converter 100 according to the first embodiment. In the example of FIG. 7, the reference ON-duty DTac is input to a positive input terminal of the comparator 942, and the internal carrier Car is input to a negative input terminal of the comparator 942. Therefore, the comparator 942: outputs 1 as the high-speed switching signal S1 in a case of reference ON-duty DTac>internal carrier Car; and outputs 0 as the high-speed switching signal S1 in a case of reference ON-duty DTac<internal carrier Car. In the example of FIGS. 7, 1 is high active at a level higher than 0, but 1 may be low active at a level lower than 0. The comparator 942 outputs the high-speed switching signal S1 to the NOT circuit 943 and the pulse selector 944.

The NOT circuit 943 outputs, to the pulse selector 944, the inverted synchronous rectification signal S2 obtained by inverting the high-speed switching signal S1. The inverted synchronous rectification signal S2 is a signal for causing an inverted synchronous rectification operation to be performed.

An operation of the pulse selector 944 will be described with reference to FIGS. 9 and 10. FIG. 9 is a first flowchart illustrating the operation of the pulse selector 944 included in the control circuitry 9 of the power converter 100 of the first embodiment. FIG. 10 is a second flowchart illustrating the operation of the pulse selector 944 included in the control circuitry 9 of the power converter 100 of the first embodiment. FIG. 9 illustrates a flowchart in a case where the switching pattern select signal Tsw=0 is input to the pulse selector 944, and FIG. 10 illustrates a flowchart in a case where the switching pattern select signal Tsw=1 is input to the pulse selector 944.

In a case of the switching pattern select signal Tsw=0, the pulse selector 944 performs control such that the first arm or the second arm respectively performs the high-speed switching or the low-speed switching. In a case of the switching pattern select signal Tsw=1, the pulse selector 944 performs control such that switching elements on a low side or switching elements on a high side perform switching between high-speed switching and low-speed switching every half period of a power supply frequency. In a case of the inverted synchronous rectification select signal Tsy=0, the pulse selector 944 performs control such that the inverted synchronous rectification operation is not performed. In a case of the inverted synchronous rectification select signal Tsy=1, the pulse selector 944 performs control such that the inverted synchronous rectification operation is performed.

As illustrated in FIG. 9, in the case where the switching pattern select signal Tsw=0 is input, and if the inverted synchronous rectification select signal Tsy=1 is input (step S11: Yes) and the alternating-current voltage Vac is positive (step S12: Yes), the pulse selector 944 outputs, as the gate signal Vgs, the inverted synchronous rectification signal S2 to the switching element 21. In FIG. 9, the description of “pulse_21→S2” means this control. Under a similar condition, the pulse selector 944 outputs, as the gate signal Vgs, the high-speed switching signal S1 to the switching element 22. The pulse selector 944 outputs, as the gate signal Vgs, a signal of 0 at all times to the switching element 23 for turning-off thereof at all times. In FIG. 9, the description of “pulse_23→0” means this control. The pulse selector 944 outputs, as the gate signal Vgs, a signal of 1 at all times to the switching element 24 for turning-on thereof at all times (step S13).

As illustrated in FIG. 9, in the case where the switching pattern select signal Tsw=0 is input, and if the inverted synchronous rectification select signal Tsy=1 is input (Step S11: Yes) and the alternating-current voltage Vac is negative (Step S12: No), the pulse selector 944 outputs, as the gate signals Vgs: the high-speed switching signal S1 to the switching element 21; the inverted synchronous rectification signal S2 to the switching element 22; the signal of 1 at all times to the switching element 23 for turning-on thereof at all times; and the signal of 0 at all times to the switching element 24 for turning-off thereof at all times (Step S14). In the present embodiment, in a case where the switching pattern select signal Tsw=0 is input to the pulse selector 944, the inverted synchronous rectification select signal Tsy=1 is input thereto, and both cases are included where the alternating-current voltage Vac is positive and where the alternating-current voltage Vac is negative, the gate signals Vgs are defined as the gate signals Vgs of pattern 1. In a case of the gate signals Vgs of pattern 1, the gate signals Vgs output from the control circuitry 9 to the respective switching elements 21 to 24 of the converter 2, that is, the gate signals Vgs input from the control circuitry 9 to the respective switching elements 21 to 24 of the converter 2 are the gate signals Vgs 21 to Vgs 24 illustrated in FIG. 3.

As illustrated in FIG. 9, in the case where the switching pattern select signal Tsw=0 is input, and if the inverted synchronous rectification select signal Tsy=0 is input (Step S11: No) and the alternating-current voltage Vac is positive (Step S15: Yes), the pulse selector 944 outputs, as the gate signals Vgs: the signal of 0 at all times to the switching element 21 for turning-off thereof at all times; the high-speed switching signal S1 to the switching element 22; the signal of 0 at all times to the switching element 23 for turning-off thereof at all times; and the signal of 1 at all times to the switching element 24 for turning-on thereof at all times (Step S16). In the case where the switching pattern select signal Tsw=0 is input, and if the inverted synchronous rectification select signal Tsy=0 is input (Step S11: No) and the alternating-current voltage Vac is negative (Step S15: No), the pulse selector 944 outputs, as the gate signals Vgs: the high-speed switching signal S1 to the switching element 21; the signal of 0 at all times to the switching element 22 for turning-off thereof at all times; the signal of 1 at all times to the switching element 23 for turning-on thereof at all times; and the signal of 0 at all times to the switching element 24 for turning-off thereof at all times (Step S17). In the first embodiment, in a case where the switching pattern select signal Tsw=0 is input to the pulse selector 944, the inverted synchronous rectification select signal Tsy=0 is input thereto, and both cases are included where the alternating-current voltage Vac is positive and where the alternating-current voltage Vac is negative, the gate signals Vgs are defined as the gate signals Vgs of pattern 2.

In the example of FIG. 9, the pulse selector 944 outputs the signals such that the switching elements 21 and 22 as the first arm perform the high-speed switching, but the pulse selector 944 may output the gate signals Vgs such that the switching elements 23 and 24 as the second arm perform the high-speed switching. In the power converter 100 of the first embodiment, the control circuitry 9 outputs the gate signals Vgs 21 to Vgs 24 to the switching elements 21 to 24 of the converter 2, but there is no limitation thereto. In the power converter 100, the control circuitry 9 may output, to the converter 2, drive pulses each having a voltage value smaller than the gate signals Vgs 21 to Vgs 24, and the converter 2 may generate the gate signals Vgs 21 to Vgs 24 from the drive pulses in an internal circuit (not illustrated).

As illustrated in FIG. 10, in the case where the switching pattern select signal Tsw=1 is input, and if the inverted synchronous rectification select signal Tsy=1 is input (Step S21: Yes) and the alternating-current voltage Vac is positive (Step S22: Yes), the pulse selector 944 outputs, as the gate signals Vgs: the inverted synchronous rectification signal S2 to the switching element 21; the high-speed switching signal S1 to the switching element 22; the signal of 0 at all times to the switching element 23; and the signal of 1 at all times to the switching element 24 (Step S23). In the case where the switching pattern select signal Tsw=1 is input, and if the inverted synchronous rectification select signal Tsy=1 is input (Step S21: Yes) and the alternating-current voltage Vac is negative (Step S22: No), the pulse selector 944 outputs, as the gate signals Vgs: the signal of 0 at all times to the switching element 21; the signal of 1 at all times to the switching element 22; the inverted synchronous rectification signal S2 to the switching element 23; and the high-speed switching signal S1 to the switching element 24 (Step S24). In the first embodiment, in a case where the switching pattern select signal Tsw=1 is input to the pulse selector 944, the inverted synchronous rectification select signal Tsy=1 is input thereto, and both cases are included where the alternating-current voltage Vac is positive and where the alternating-current voltage Vac is negative, the gate signals Vgs are defined as the gate signals Vgs of pattern 3.

As illustrated in FIG. 10, in the case where the switching pattern select signal Tsw=1 is input, and if the inverted synchronous rectification select signal Tsy=0 is input (Step S21: No) and the alternating-current voltage Vac is positive (Step S25: Yes), the pulse selector 944 outputs, as the gate signals Vgs: the signal of 0 at all times to the switching element 21; the high-speed switching signal S1 to the switching element 22; the signal of 0 at all times to the switching element 23; and the signal of 1 at all times to the switching element 24 (Step S26). In the case where the switching pattern select signal Tsw=1 is input, and if the inverted synchronous rectification select signal Tsy=0 is input (Step S21: No) and the alternating-current voltage Vac is negative (Step S25: No), the pulse selector 944 outputs, as the gate signals Vgs: the signal of 0 at all times to the switching element 21; the signal of 1 at all times to the switching element 22; the signal of 0 at all times to the switching element 23; and the high-speed switching signal S1 to the switching element 24 (Step S27). In the first embodiment, in a case where the switching pattern select signal Tsw=1 is input to the pulse selector 944, the inverted synchronous rectification select signal Tsy=0 is input thereto, and both cases are included where the alternating-current voltage Vac is positive and where the alternating-current voltage Vac is negative, the gate signals Vgs are defined as the gate signals Vgs of pattern 4.

In the example of FIG. 10, the pulse selector 944 outputs the gate signals Vgs such that the switching elements on the low side of the converter 2 perform switching between the high-speed switching and the low-speed switching every half period of the frequency of the power supply, but there is no limitation thereto. The pulse selector 944 may output the gate signals Vgs such that the switching elements on the high side of the converter 2 perform switching between the high-speed switching and the low-speed switching every half period of the frequency of the power supply.

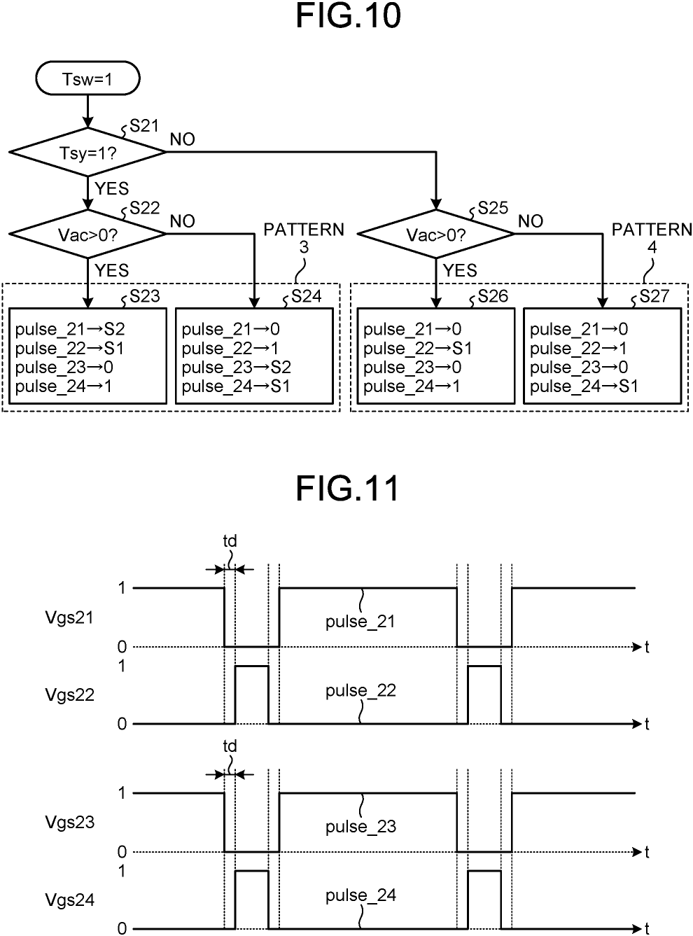

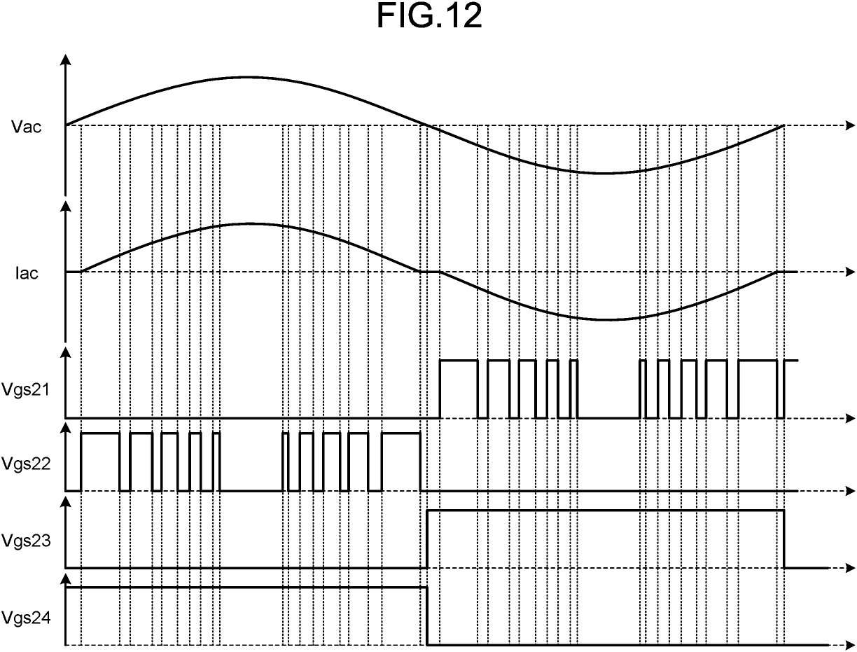

Regarding the gate signals Vgs illustrated in FIGS. 8 to 10, waveforms under the ideal condition that does not include various delays are assumed. However, in a switching element, a delay time generally occurs in a transition from an ON state to an OFF state and a transition from an OFF state to an ON state. That is, during the delay time, the switching element 21 and the switching element 22 are short-circuited, and the switching element 23 and the switching element 24 are short-circuited. Therefore, in order to prevent such a short circuit phenomenon, a dead time td is required for the converter 2. FIG. 11 is a diagram illustrating examples of signal waveforms in consideration of the dead time td in the switching elements 21 to 24 included in the converter 2 of the power converter 100 according to the first embodiment. In FIG. 11, each gate signal Vgs is set to be shorter by the dead time td on both sides of an ON period.

In the examples of FIGS. 9 and 10, the pulse selector 944 determines a switching pattern depending on whether the alternating-current voltage Vac is larger or smaller than 0 in each flowchart. However, there is no limitation thereto, and the switching pattern may be determined depending on the alternating current Iac. In a case where the switching pattern is determined depending on the alternating current Iac, the pulse selector 944 performs control to turn on one switching element of the switching elements that perform the low-speed switching at least when the alternating current Iac is in a current discontinuous mode.

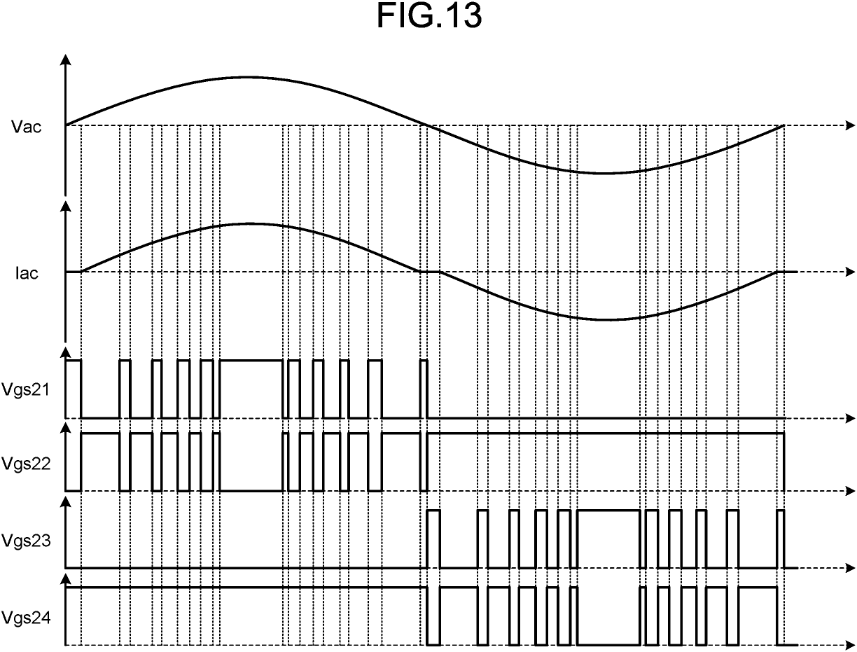

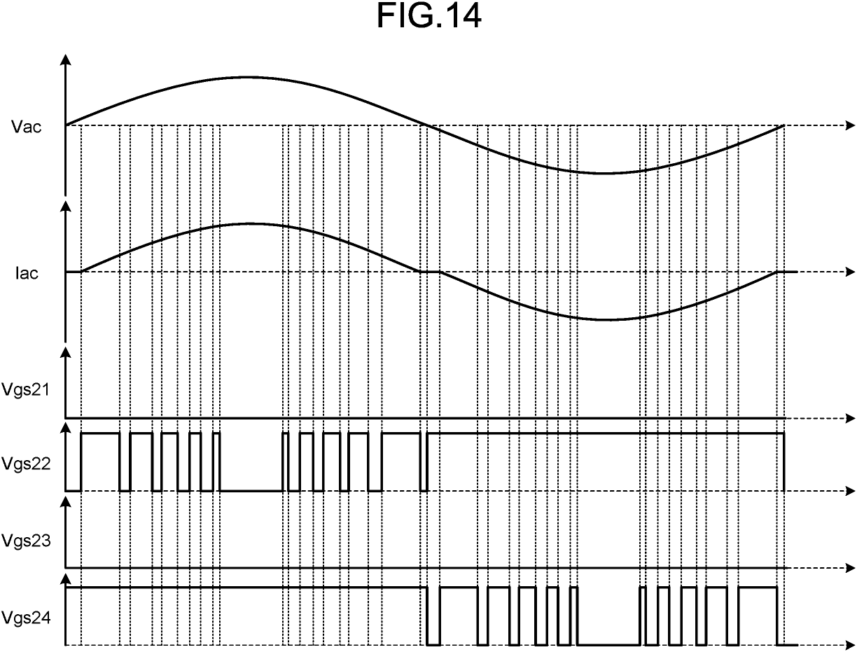

FIGS. 12 to 14 illustrate waveforms of the gate signals Vgs of patterns 2 to 4. FIG. 12 is a diagram illustrating examples of the gate signals Vgs 21 to Vgs 24 in a case of pattern 2 output to the converter 2 by the control circuitry 9 of the power converter 100 according to the first embodiment. FIG. 13 is a diagram illustrating examples of the gate signals Vgs 21 to Vgs 24 in a case of pattern 3 output to the converter 2 by the control circuitry 9 of the power converter 100 according to the first embodiment. FIG. 14 is a diagram illustrating examples of the gate signals Vgs 21 to Vgs 24 in a case of pattern 4 output to the converter 2 by the control circuitry 9 of the power converter 100 according to the first embodiment. A current path inside the converter 2 in the case of pattern 3 is similar to the current path illustrated in FIG. 4.

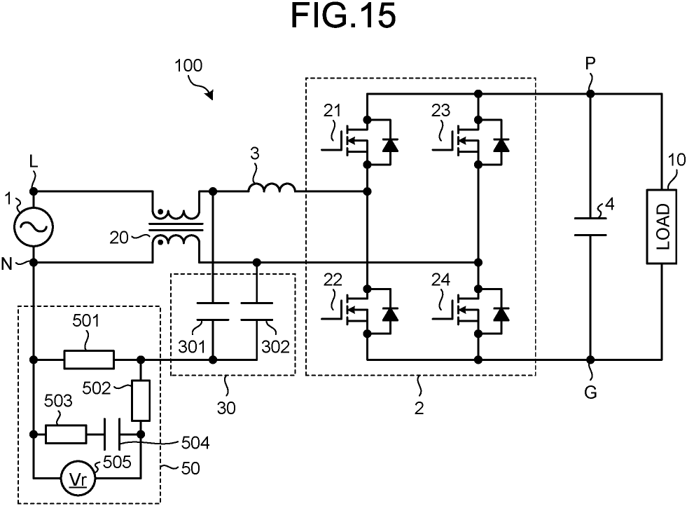

Next, as a method for suppressing noise in the power converter 100, a method for reducing a leakage current that causes noise will be described. First, a method for measuring a leakage current flowing through the power converter 100 will be described. FIG. 15 is a diagram illustrating an example of a method for measuring the leakage current flowing through the power converter 100 according to the first embodiment. The power converter 100 illustrated in FIG. 15 is obtained by adding a leakage ammeter 50, which detects a leakage current value, to the power converter 100 illustrated in FIG. 2. One end of the leakage ammeter 50 is connected to a common terminal of the Y capacitor 30, and another end thereof is connected to one pole of the alternating-current power supply 1. In the example illustrated in FIG. 15, the one end of the leakage ammeter 50 is connected to the common terminal of the Y capacitor 30. However, in a case where the power converter 100 does not include the Y capacitor 30, the one end of the leakage ammeter 50 is connected to a ground terminal of the power converter 100. In addition, when the leakage ammeter 50 measures the leakage current in the power converter 100, the E terminal of the alternating-current power supply 1 is not connected anywhere.

The leakage ammeter 50 includes: a first resistor 501 of 1 kΩ; a second resistor 502 of 10 kΩ; a third resistor 503 of 579 Ω; a third capacitor 504 of 11.225 nF; and an effective value meter 505. A method for connecting each element is as illustrated in FIG. 15. Specifically, the second resistor 502, the third capacitor 504, and the third resistor 503 are connected in parallel to the first resistor 501. The effective value meter 505 is connected in parallel to the third capacitor 504 and the third resistor 503. The effective value meter 505 reads out a value of a voltage across the first resistor 501 attenuated by the second resistor 502, the third resistor 503, and the third capacitor 504, which serve as a low-pass filter. The value read out by the effective value meter 505 is the leakage current value. In the effective value meter 505, the unit of the value to be read is volt (V), but the unit is replaced with milliampere (mA) when the value is converted into the leakage current value. This is because the effective value meter 505 detects the value of the voltage across the first resistor 501 of 1 kΩ, and the unit is adjusted when the voltage is converted into the current.

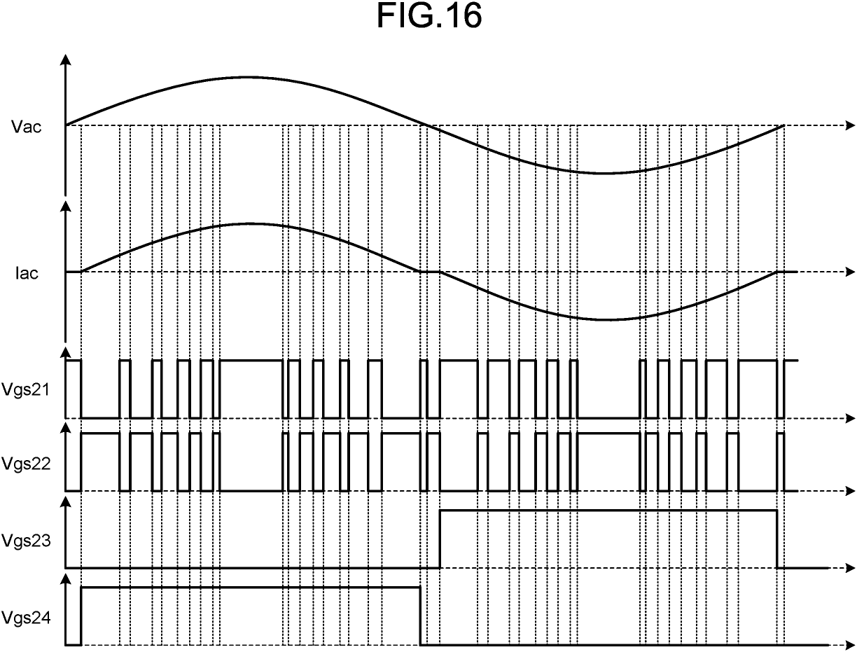

FIG. 16 is a diagram illustrating, as comparative examples, examples of the gate signals Vgs 21 to Vgs 24 for the switching elements 21 to 24 when the switching elements 23 and 24 included in the converter 2 of the power converter 100 are switched in synchronization with the alternating current Iac. Differences from FIG. 3 are the gate signal Vgs 23 for the switching element 23 and the gate signal Vgs 24 for the switching element 24. In FIG. 3, the switching elements 23 and 24 perform switching at a timing when the polarity of the alternating-current voltage Vac changes, whereas in FIG. 16, the switching elements 23 and 24 perform switching at a timing when the alternating current Iac becomes zero or changes from zero.

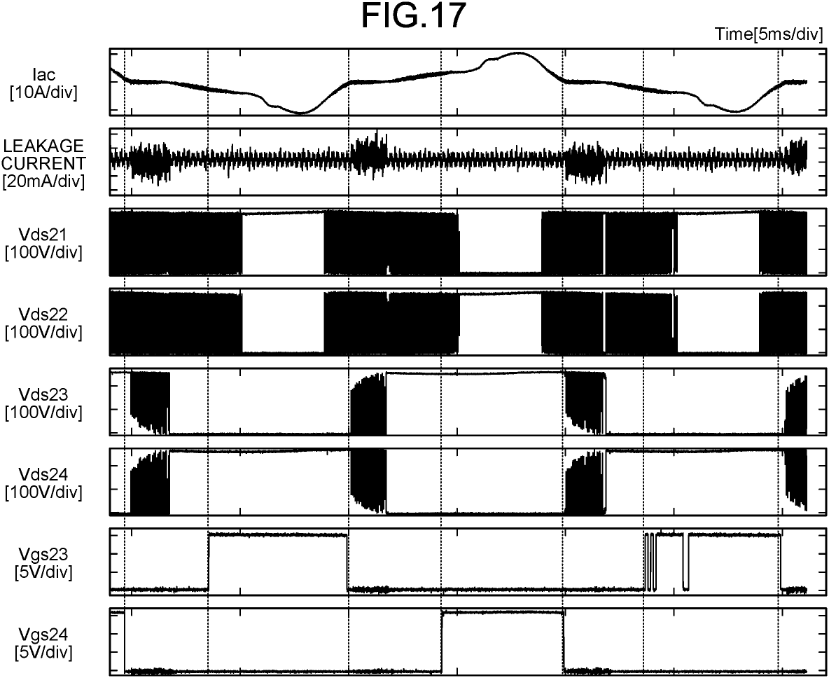

FIG. 17 is a diagram illustrating, as comparative examples, respective signal waveforms and a waveform obtained by measuring a leakage current in a case where the switching elements 21 to 24 included in the converter 2 of the power converter 100 operate with the gate signals Vgs 21 to Vgs 24 illustrated in FIG. 16. FIG. 17 illustrates, from the top to the bottom, respective waveforms of: the alternating current Iac; the leakage current; a drain-source voltage Vds 21 of the switching element 21; a drain-source voltage Vds 22 of the switching element 22; a drain-source voltage Vds 23 of the switching element 23; a drain-source voltage Vds 24 of the switching element 24; the gate signal Vgs 23 for the switching element 23; and the gate signal Vgs 24 for the switching element 24. It can be confirmed from the waveforms of the drain-source voltage Vds 21 of the switching element 21 and the drain-source voltage Vds 22 of the switching element 22 illustrated in FIG. 17 that the switching elements 21 and 22 perform the high-speed switching. In addition, it can be confirmed from the waveforms of the drain-source voltage Vds 23 of the switching element 23 and the drain-source voltage Vds 24 of the switching element 24 illustrated in FIG. 17 that the switching elements 23 and 24 perform switching in synchronization with the alternating current Iac. The drain-source voltage Vds indicates a voltage difference between the drain and the source of each switching element.

In FIG. 17, in each period of a minute current during which the alternating current Iac becomes substantially zero, the drain-source voltages Vds 23 and Vds 24 fluctuate although an OFF signal is input to the switching element 23 as the gate signal Vgs 23 and an OFF signal is input to the switching element 24 as the gate signal Vgs 24. As illustrated in FIG. 17, the leakage current increases in the periods. As described above, in the power converter 100, when the switching elements that perform the low-speed switching are turned off while the switching elements that perform the high-speed switching are operating in each period of the minute current during which the alternating current Iac becomes zero, the drain-source voltages Vds of the switching elements that perform the low-speed switching fluctuate and the leakage current increases.

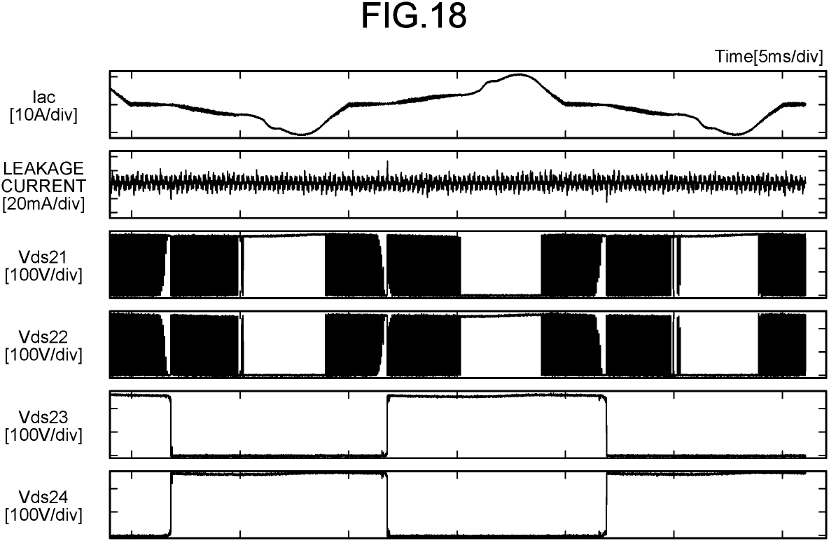

FIG. 18 is a diagram illustrating waveforms obtained by measuring respective signals and a leakage current in a case where the switching elements 21 to 24 included in the converter 2 of the power converter 100 according to the first embodiment operate with the gate signals Vgs 21 to Vgs 24 illustrated in FIG. 3. FIG. 18 illustrates waveforms of the leakage current and the like when the power converter 100 switches the switching elements 23 and 24 that perform the low-speed switching depending on the polarity of the alternating-current voltage Vac as illustrated in FIG. 3. FIG. 18 illustrates, from the top to the bottom, respective waveforms of: the alternating current Iac; the leakage current; the drain-source voltage Vds 21 of the switching element 21; the drain-source voltage Vds 22 of the switching element 22; the drain-source voltage Vds 23 of the switching element 23; and the drain-source voltage Vds 24 of the switching element 24. It can be confirmed from the waveforms of the drain-source voltage Vds 23 of the switching element 23 and the drain-source voltage Vds 24 of the switching element 24 illustrated in FIG. 18 that the switching elements 23 and 24 perform switching depending on the polarity of the alternating-current voltage Vac. In the power converter 100, the control circuitry 9 performs such control, that is, the switching of the switching elements 23 and 24 performing the low-speed switching depending on the polarity of the alternating-current voltage Vac, and thereby a period is shortened during which both the switching elements performing the low-speed switching are turned off, and the increase in the leakage current can be suppressed.

As described above, the power converter 100 can suppress the leakage current which is a kind of noise by changing the switching pattern of the switching elements 21 to 24 of the converter 2, and can promote the effect of the noise filter constituted by the common mode choke coil 20, the Y capacitor 30, and the like. In the power 100, the control circuitry 9 controls the switching elements 21 to 24 such that a potential fluctuation due to the switching operation is suppressed: between the P terminal and the L terminal; or between the G terminal and the N terminal. Wherein, the P terminal is a positive direct-current terminal of the converter 2; the L terminal is one terminal of the alternating-current power supply 1; the G terminal is a negative direct-current terminal of the converter 2; and the N terminal is another terminal of the alternating-current power supply 1. In addition, the control circuitry 9 can change a method for fixing a potential between the P terminal and the L terminal or between the G terminal and the N terminal by changing the switching pattern of the switching elements 21 to 24.

Among the switching elements 21 to 24 of the converter 2: the first arm in which the switching elements 21 and 22 are connected in series; and the second arm in which the switching elements 23 and 24 are connected in series; the control circuitry 9 performs the high-speed switching in which power supply short circuit and power supply are performed at a first speed based on a predefined frequency in one of the arms. The control circuitry 9 performs the low-speed switching in which switching is performed at a second speed lower than the first speed in synchronization with the power supply frequency of the alternating-current power supply 1 in another of the arms. The first speed may be not a constant speed but a variable speed. Regarding either one of the switching elements 21 and 23 on the high side or the switching elements 22 and 24 on the low side among the switching elements 21 to 24 of the converter 2, the control circuitry 9 may perform switching from the high-speed switching once and switching from the low-speed switching once within one period of the power supply frequency of the alternating-current power supply 1. In addition, the control circuitry 9 switches the switching elements depending on the polarity of the alternating-current voltage Vac of the alternating-current power supply 1 in the low-speed switching. In the case of the inverted synchronous rectification select signal Tsy=0, the control circuitry 9 switches, out of two of the switching elements that perform the high-speed switching, a first switching element as a main switching element for the high-speed switching, and turns off a second switching element. In the case of the inverted synchronous rectification select signal Tsy=1, the control circuitry 9 switches, out of two of the switching elements that perform the high-speed switching, the first switching element as a main switching element for the high-speed switching, and inversely synchronizes the second switching element with respect to the first switching element to switch the second switching element.

Next, a hardware configuration of the control circuitry included in the power converter 100 will be described. FIG. 19 is a diagram illustrating an example of a hardware configuration that realizes the control circuitry 9 included in the power converter 100 according to the first embodiment. The control circuitry 9 is realized by a processor 201 and a memory 202.

The processor 201 is a central processing unit (CPU, also referred to as a processing device, an arithmetic device, a microprocessor, a microcomputer, a processor, or a digital signal processor (DSP)), or system large scale integration (LSI). As the memory 202, a nonvolatile or volatile semiconductor memory such as a random access memory (RAM), a read only memory (ROM), a flash memory, an erasable programmable read only memory (EPROM), or an electrically erasable programmable read only memory (EEPROM (registered trademark)) can be exemplified. The memory 202 is not limited thereto, and may be a magnetic disk, an optical disk, a compact disc, a mini disk, or a digital versatile disc (DVD). The control circuitry 9 may be configured with an electric circuit element or the like such as an analog circuit or a digital circuit.

As described above, according to the first embodiment, in the power converter 100, the control circuitry 9 controls the switching elements 21 to 24 such that a potential fluctuation due to the switching operation is suppressed between the P terminal of the converter 2 and the L terminal of the alternating-current power supply 1 or between the G terminal of the converter 2 and the N terminal of the alternating-current power supply 1. Consequently, the power converter 100 can achieve both suppression of noise and stability of control while reducing the leakage current that causes noise. In addition, by the common mode choke coil 20 and the Y capacitor 30 which are noise filters being connected, the power converter 100 can further reduce the leakage current that causes noise.

### Second Embodiment

In a second embodiment, a case will be described where the power converter 100 includes a configuration for further reducing a leakage current.

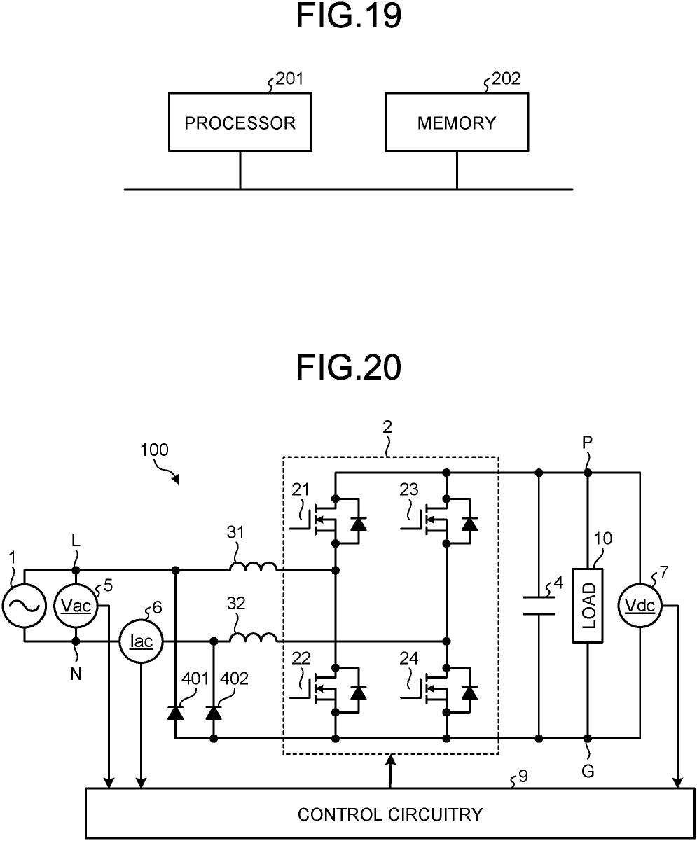

FIG. 20 is a diagram illustrating an example configuration of the power converter 100 according to the second embodiment. The power converter 100 illustrated in FIG. 20 includes: the alternating-current power supply 1; the converter 2; a first reactor 31; a second reactor 32; the smoothing capacitor 4; a first diode 401; a second diode 402; the alternating-current voltage detector 5; the alternating current detector 6; the direct-current voltage detector 7; the control circuitry 9; and the load 10.

In the power converter 100, the L terminal of the alternating-current power supply 1 is connected to one end of the first reactor 31, and another end of the first reactor 31 is connected to the one alternating-current terminal of the converter 2. In addition, the N terminal of the alternating-current power supply 1 is connected to one end of the second reactor 32, and another end of the second reactor 32 is connected to the another alternating-current terminal of the converter 2. A cathode of the first diode 401 is connected to the one end of the first reactor 31, and a cathode of the second diode 402 is connected to the one end of the second reactor 32. The anodes of the first diode 401 and the second diode 402 are both connected to the negative G terminal which is the direct-current terminal of the converter 2. The alternating-current voltage detector 5 is connected in parallel to both ends of the alternating-current power supply 1. The alternating current detector 6 is connected in series between the alternating-current power supply 1 and cathode connection ends of the first diode 401 and the second diode 402. In the second embodiment, one of the first reactor 31 and the second reactor 32 may be the reactor 3 of the first embodiment.

The smoothing capacitor 4, the load 10, and the direct-current voltage detector 7 are each connected in parallel between the P terminal and the G terminal which are the direct-current terminals in the converter 2. The control circuitry 9 acquires values detected by the alternating-current voltage detector 5, the alternating current detector 6, and the direct-current voltage detector 7, that is, detection results. The control circuitry 9 generates and outputs the gate signals Vgs for controlling the switching elements 21 to 24 of the converter 2 on the basis of the detection results of the alternating-current voltage detector 5, the alternating current detector 6, and the direct-current voltage detector 7. Regarding the alternating-current power input to the converter 2, the power converter 100 performs power factor improvement, bus voltage control, and the like, by controlling the switching elements 21 to 24 of the converter 2 on the basis of the detection results of the alternating-current voltage detector 5, the alternating current detector 6, and the direct-current voltage detector 7.

Although not illustrated in FIG. 20, the power converter 100 of the second embodiment may include at least one of the common mode choke coil 20 and the Y capacitor 30 which are noise filters, similarly to the power converter 100 of the first embodiment illustrated in FIG. 2.

The power converter 100 to which the first diode 401 and the second diode 402 illustrated in FIG. 20 are connected operates the switching elements such that a current circulates through the power supply short-circuit path on a low side as in the switching patterns illustrated in FIGS. 13, 14, and the like. The power converter 100 can maximize an effect obtained by connecting the first diode 401 and the second diode 402 by the current circulating through the power supply short-circuit path on the low side. Regarding the switching elements that perform the low-speed switching, the power converter 100 performs the switching depending on the polarity of the alternating-current voltage Vac in the first embodiment, but the switching may be performed depending on the polarity of the alternating current Iac in a circuit configuration of the second embodiment in which the first diode 401 and the second diode 402 illustrated in FIG. 20 are connected.

FIG. 21 is a diagram illustrating examples of a current path when the control circuitry 9 of the power converter 100 according to the second embodiment causes a current to circulate through the switching elements 22 and 24 on the low side in the power supply short-circuit mode. The power converter 100 can cause a current to flow through the first diode 401 and the second diode 402 in the power supply short-circuit mode and the load power supplying mode by causing the current to circulate through the switching elements 22 and 24 on the low side of the converter 2. The power converter 100 can fix the potentials of the drain-source voltages Vds of the switching elements 22 and 24 on the low side of the converter 2 to zero by the current flowing through the first diode 401 and the second diode 402. Consequently, the potentials of the drain-source voltages Vds of the switching elements 22 and 24 on the low side of the converter 2 do not fluctuate, and thus the power converter 100 can reduce the leakage current.

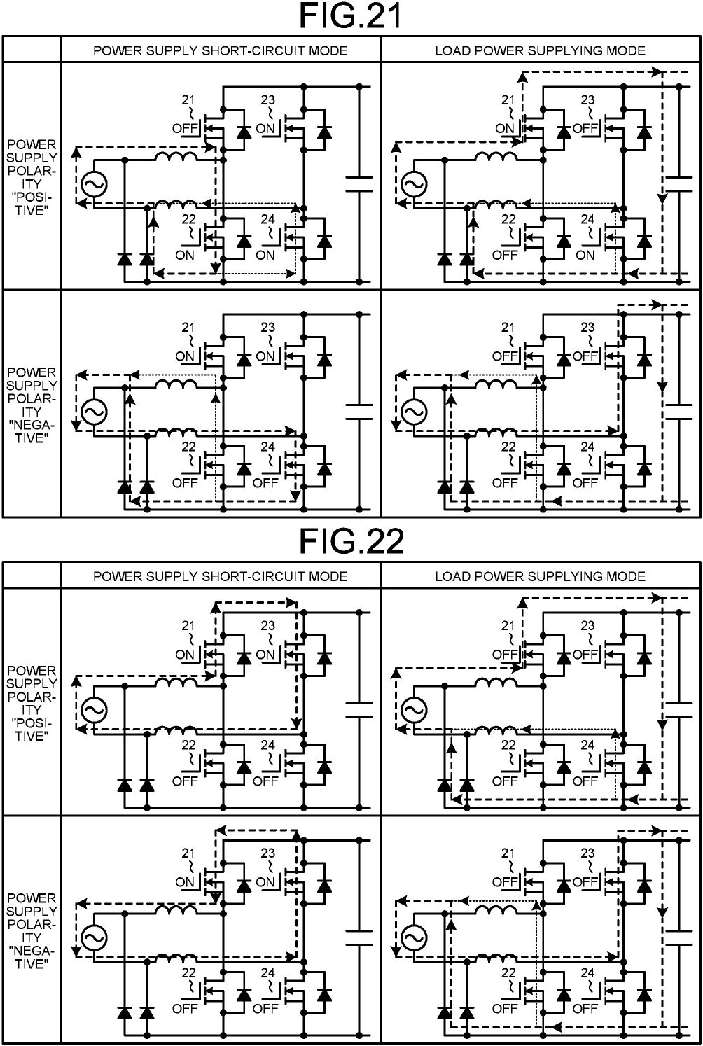

FIG. 22 is a diagram illustrating, as comparative examples, examples of a current path when the control circuitry 9 of the power converter 100 causes a current to circulate through the switching elements 21 and 23 on the high side in the power supply short-circuit mode. The power converter 100 cannot cause a current to flow through the first diode 401 and the second diode 402 in the power supply short-circuit mode in a case of causing the current to circulate through the switching elements 21 and 23 on the high side of the converter 2. As a result, in the power supply short-circuit mode, the power converter 100 cannot suppress the fluctuation in the drain-source voltages Vds of the switching elements 22 and 24 on the low side, and cannot obtain the maximum effect of reducing the leakage current.

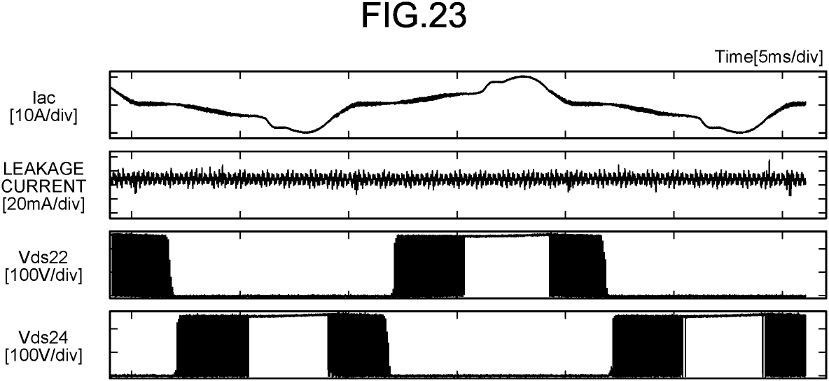

FIG. 23 is a diagram illustrating a waveform obtained by measuring a leakage current when a current is caused to circulate through the switching elements 22 and 24 on the low side in the power supply short-circuit mode in the power converter 100 according to the second embodiment to which the first diode 401 and the second diode 402 illustrated in FIG. 20 are connected. FIG. 23 illustrates, from the top to the bottom, respective waveforms of the alternating current Iac, the leakage current, and the drain-source voltages Vds 22 and Vds 24 of the switching elements 22 and 24 on the low side. The respective waveforms illustrated in FIG. 23 are those in a case where the switching elements that perform the low-speed switching are synchronized with the polarity of the alternating current Iac. From the waveform of the leakage current illustrated in FIG. 23, it can be confirmed that the leakage current does not increase even in a period during which the alternating current Iac is a minute current.

As described above, in the power converter 100, regarding either one of the switching elements 21 and 23 on the high side or the switching elements 22 and 24 on the low side among the switching elements 21 to 24 of the converter 2, the control circuitry 9 performs switching from the high-speed switching once and switching from the low-speed switching once within one period of the power supply frequency of the alternating-current power supply 1. In the low-speed switching, the control circuitry 9 may switch the switching elements depending on the polarity of the alternating-current voltage Vac of the alternating-current power supply 1, or may switch the switching elements depending on the polarity of the alternating current Iac of the alternating-current power supply 1. In the case of the inverted synchronous rectification select signal Tsy=0, the control circuitry 9 switches, out of two of the switching elements that perform the high-speed switching, a first switching element as a main switching element for the high-speed switching, and turns off a second switching element. In the case of the inverted synchronous rectification select signal Tsy=1, the control circuitry 9 switches, out of two of the switching elements that perform the high-speed switching, the first switching element as a main switching element for the high-speed switching, and inversely synchronizes the second switching element with the first switching element to switch the second switching element.

As described above, according to the second embodiment, since the power converter 100 includes the first reactor 31, the second reactor 32, the first diode 401, and the second diode 402, it is possible to further reduce the leakage current that causes noise.

### Third Embodiment

In a third embodiment, an example application of the power converter 100 described in the first embodiment and the second embodiment will be described.

FIG. 24 is a diagram illustrating an example configuration of a motor driver 101 according to the third embodiment including the power converter 100 of the first and second embodiments. The motor driver 101 includes the power converter 100 described in the first and second embodiments and an inverter 102 which is the load 10. FIG. 24 illustrates a state where the alternating-current power supply 1 and a motor 103 are connected to the motor driver 101. In the motor driver 101, the inverter 102 is connected to direct-current terminals of the converter 2 included in the power converter 100. The motor 103 is connected to an output terminal of the inverter 102. The inverter 102 converts direct-current power output from the power converter 100 into alternating-current power and applies the alternating-current power to the motor 103, thereby driving the motor 103. The motor driver 101 illustrated in FIG. 24 can be applied to products such as blowers, compressors, and air conditioners.

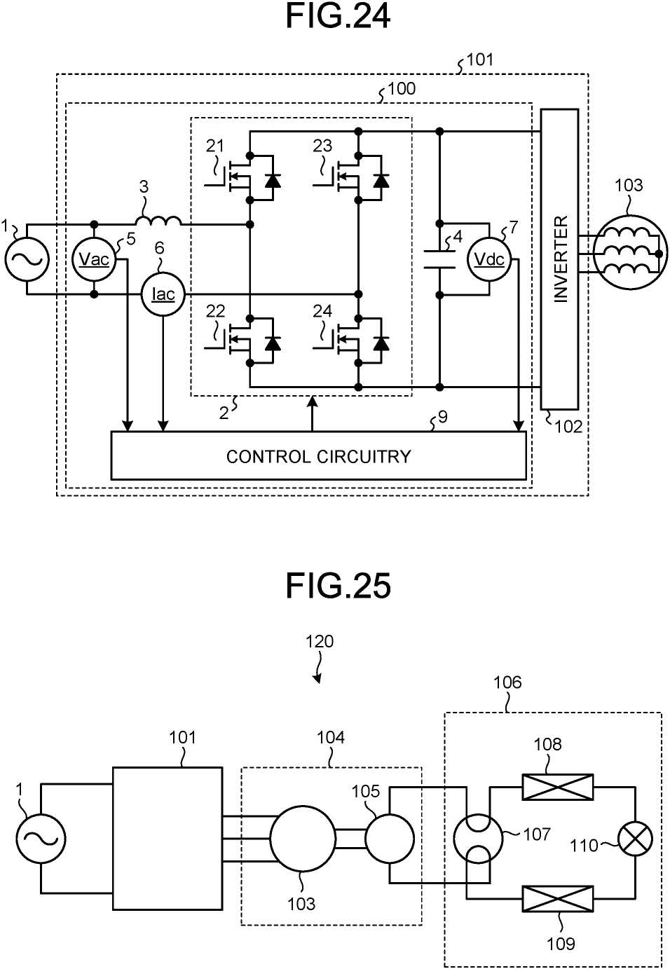

FIG. 25 is a diagram illustrating an example configuration of an air conditioner 120 according to the third embodiment including the motor driver 101 illustrated in FIG. 24. The air conditioner 120 includes the motor driver 101, a compressor 104, and a refrigeration cycler 106. FIG. 25 illustrates a state where the alternating-current power supply 1 is connected to the air conditioner 120. The compressor 104 includes: the motor 103 driven by alternating-current power output from the inverter 102; and a compression element 105. The motor 103 is connected to an output terminal of the motor driver 101. The motor 103 is coupled to the compression element 105. The refrigeration cycler 106 includes: a four-way valve 107; an indoor heat exchanger 108; an outdoor heat exchanger 109; and an expansion valve 110. A flow path of a refrigerant circulating inside the air conditioner 120 is configured as follows: the refrigerant flows out from the compression element 105 and returns to the compression element 105 via the four-way valve 107, the indoor heat exchanger 108, the expansion valve 110, the outdoor heat exchanger 109, and again via the four-way valve 107. The motor driver 101 receives the alternating-current voltage Vac supplied from the alternating-current power supply 1, and rotates the motor 103. In the compressor 104, by the rotation of the motor 103, the compression element 105 executes a compression operation of the refrigerant, and causes the refrigerant to circulate inside the refrigeration cycler 106.

FIG. 26 is a diagram illustrating a part of a propagation path of a leakage current mainly in an outdoor unit 140 in the air conditioner 120 according to the third embodiment. In the air conditioner 120, an indoor unit 130 and the outdoor unit 140 are connected via a pipe 115. A substrate GND 116 of the motor driver 101 mounted on the outdoor unit 140 is connected from the Y capacitor 30 to a housing 141 of the outdoor unit 140 via a jumper wire 113. In the outdoor unit 140, the leakage current propagates through the housing 141 of the outdoor unit 140 from a heat sink 111 on the substrate of the motor driver 101, an outdoor unit fan 112, the compressor 104, and the like, via stray capacities 114. Although only some of the stray capacities 114 are illustrated in FIG. 26, actually, the stray capacities 114 capacitively coupled to the housing 141 of the outdoor unit 140 also exist in the common mode choke coil 20, the reactor 3, and the like. The heat sink 111 on the substrate of the motor driver 101 is not grounded in the example of FIG. 26, but may be grounded.

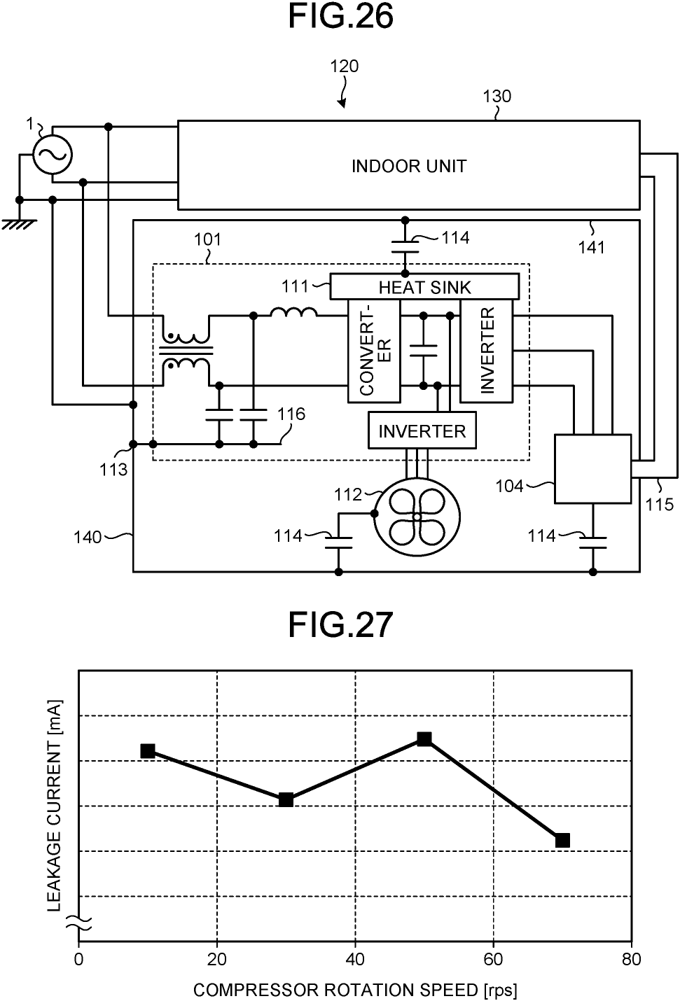

FIG. 27 is a diagram illustrating a measurement result of a leakage current depending on a compressor rotation speed of the compressor 104 mounted on the air conditioner 120 according to the third embodiment or the like. The compressor rotation speed is actually a rotation speed of the motor 103 included in the compressor 104. As illustrated in FIG. 27, the leakage current is maximized in a region where the compressor rotation speed is low, i.e., a low-rotation region, and a region where the compressor rotation speed is medium, i.e., a medium-rotation region. The low-rotation region is, for example, a region where the compressor rotation speed is 5 to 10 rps. The medium-rotation region is, for example, a region where the compressor rotation speed is 40 to 70 rps. Therefore, the power converter 100 can obtain an effect of further suppressing the leakage current by applying the technique of suppressing the leakage current in a region where the compressor rotation speed is low to medium. In the power converter 100, the control circuitry 9 controls the switching of the switching elements 21 to 24 as described above in a region where the rotation speed of the compressor 104 is 5 rps to 70 rps.

As described above, the power converter 100 can be applied to various products.

The configurations described in the above embodiments are merely examples and can be combined with other known technology, the embodiments can be combined with each other, and part of the configurations can be omitted or modified without departing from the gist thereof.

1. A power converter comprising:
a converter including four switching elements in a full bridge configuration, the converter is adapted to convert alternating-current power supplied from an alternating-current power supply into direct-current power;
a reactor provided between the alternating-current power supply and the converter;
a smoothing capacitor connected between direct-current terminals of the converter;
an alternating-current voltage detector adapted to detect an alternating-current voltage output from the alternating-current power supply;
an alternating current detector adapted to detect a current flowing through the reactor; and
a control circuitry adapted to control a switching operation of the switching elements, wherein
the control circuitry is adapted to control the switching elements such that a potential fluctuation due to the switching operation is suppressed:
between a P terminal and an L terminal; or
between a G terminal and an N terminal, wherein
the P terminal is a positive direct-current terminal of the converter,
the L terminal is one terminal of the alternating-current power supply,
the G terminal is a negative direct-current terminal of the converter, and
the N terminal is another terminal of the alternating-current power supply, wherein the power converter further includes:
a first reactor having one end connected to the L terminal of the alternating-current power supply and another end connected to one alternating-current terminal of the converter;
a second reactor having one end connected to the N terminal of the alternating-current power supply and another end connected to another alternating-current terminal of the converter;
a first diode having a cathode connected to the one end of the first reactor and an anode connected to the G terminal; and
a second diode having a cathode connected to the one end of the second reactor and an anode connected to the G terminal, wherein
one of the first reactor and the second reactor is the reactor.

2. The power converter according to claim 1, comprising:
a common mode choke coil adapted to reduce noise, the common mode choke coil being connected between the alternating-current power supply and the reactor.

3. The power converter according to claim 1, comprising:
a Y capacitor, wherein
the Y capacitor includes:
a first capacitor connected in parallel to the L terminal and an E terminal that is a ground wire; and
a second capacitor connected in parallel to the N terminal and the E terminal.

4. The power converter according to claim 1, wherein
the control circuitry is adapted to change a method for fixing a potential between the P terminal and the L terminal or between the G terminal and the N terminal by changing a switching pattern of the switching elements.

5. (canceled)

6. A power converter comprising:
a converter including four switching elements in a full bridge configuration, the converter is adapted to convert alternating-current power supplied from an alternating-current power supply into direct-current power;
a reactor provided between the alternating-current power supply and the converter;
a smoothing capacitor connected between direct-current terminals of the converter;
an alternating-current voltage detector adapted to detect an alternating-current voltage output from the alternating-current power supply;
an alternating current detector adapted to detect a current flowing through the reactor; and
a control circuitry adapted to control a switching operation of the switching elements, wherein
the control circuitry is adapted to control the switching elements such that a potential fluctuation due to the switching operation is suppressed:
between a P terminal and an L terminal; or
between a G terminal and an N terminal, wherein
the P terminal is a positive direct-current terminal of the converter,
the L terminal is one terminal of the alternating-current power supply,
the G terminal is a negative direct-current terminal of the converter, and
the N terminal is another terminal of the alternating-current power supply, wherein
the control circuitry is adapted to change a method for fixing a potential between the P terminal and the L terminal or between the G terminal and the N terminal by changing a switching pattern of the switching elements, wherein
in two arms in which the switching elements of the converter are connected in series, the control circuitry is adapted to:
perform a high-speed switching in which power supply short circuit and power supply are performed at a first speed based on a predefined frequency in one of the arms; and
perform a low-speed switching in which switching is performed at a second speed lower than the first speed in synchronization with a power supply frequency of the alternating-current power supply in another of the arms.

7. The power converter according to claim 1, wherein
regarding either one of switching elements on a high side or switching elements on a low side among the switching elements of the converter, the control circuitry is adapted to perform switching from high-speed switching in which power supply short circuit and power supply are performed at a first speed based on a predefined frequency once and switching from low-speed switching in which switching is performed at a second speed lower than the first speed in synchronization with a power supply frequency of the alternating-current power supply once within one period of a power supply frequency of the alternating-current power supply.

8. The power converter according to claim 6, wherein
the control circuitry is adapted to switch the switching elements depending on a polarity of an alternating-current voltage of the alternating-current power supply in the low-speed switching.

9. The power converter according to claim 7, wherein
the control circuitry is adapted to switch the switching elements depending on a polarity of an alternating current of the alternating-current power supply in the low-speed switching.

10. The power converter according to claim 8, wherein
out of two of the switching elements that perform the high-speed switching, the control circuitry is adapted to cause:
a first switching element to perform switching as a main switching element for the high-speed switching; and
a second switching element to perform switching that inversely synchronizes with the first switching element to switch the second switching element.

11. The power converter according to claim 8, wherein
out of two of the switching elements that perform the high-speed switching, the control circuitry is adapted to cause:
a first switching element to perform switching as a main switching element for the high-speed switching; and
a second switching element to turn off.

12. The power converter according to claim 10, wherein
an inverter and a compressor are connected, the inverter converting direct-current power output from the converter into alternating-current power, and the compressor including a motor driven by alternating-current power output from the inverter, and
the control circuitry controls switching of the switching elements in a region where the compressor is of 5 rps to 70 rps.

13. An air conditioner comprising:
the power converter according to claim 1;
an inverter connected to direct-current terminals of a converter included in the power converter and adapted to convert direct-current power into alternating-current power;
a compressor including a motor driven by alternating-current power output from the inverter and being driven by rotation of the motor; and
a refrigeration cycler through which a refrigerant circulates as the compressor is driven by the rotation of the motor.

14. The power converter according to claim 6, wherein
regarding either one of switching elements on a high side or switching elements on a low side among the switching elements of the converter, the control circuitry is adapted to perform switching from high-speed switching in which power supply short circuit and power supply are performed at a first speed based on a predefined frequency once and switching from low-speed switching in which switching is performed at a second speed lower than the first speed in synchronization with a power supply frequency of the alternating-current power supply once within one period of a power supply frequency of the alternating-current power supply.

15. The power converter according to claim 14, wherein
the control circuitry is adapted to switch the switching elements depending on a polarity of an alternating current of the alternating-current power supply in the low-speed switching.

16. The power converter according to claim 11, wherein
an inverter and a compressor are connected, the inverter converting direct-current power output from the converter into alternating-current power, and the compressor including a motor driven by alternating-current power output from the inverter, and
the control circuitry controls switching of the switching elements in a region where the compressor is of 5 rps to 70 rps.

17. An air conditioner comprising:
the power converter according to claim 6;
an inverter connected to direct-current terminals of a converter included in the power converter and adapted to convert direct-current power into alternating-current power;
a compressor including a motor driven by alternating-current power output from the inverter and being driven by rotation of the motor; and
a refrigeration cycler through which a refrigerant circulates as the compressor is driven by the rotation of the motor.
